(19) United States
(12) Patent Application Publication
(10) Pub. No.: US 2026/0363001 A1
(43) Pub. Date: Nov. 12, 2026

(54) METHOD OF MANUFACTURING A SEMICONDUCTOR DEVICE AND PHOTORESIST COMPOSITION

(71) Applicant: Taiwan Semiconductor Manufacturing Company, Ltd., Hsinchu (TW)

(72) Inventors: Shi-Cheng WANG, Hsinchu (TW); Yahru CHENG, Hsinchu (TW)

(73) Assignee: Taiwan Semiconductor Manufacturing Company, Ltd., Hsinchu (TW)

(21) Appl. No.: 19/188,715

(22) Filed: Apr. 24, 2025

(51) Int. Cl. H10P 50/00; G03F 7/004; G03F 7/11; G03F 7/16; G03F 7/30; H10P 76/20

(52) U.S. Cl. CPC H10P 50/695; G03F 7/0042; G03F 7/11; G03F 7/168; G03F 7/3014; H10P 50/692; H10P 76/204

(57) ABSTRACT

A method of manufacturing a semiconductor device includes depositing a photoresist composition over a substrate to form a photoresist layer and adding a metal complex to the photoresist composition. The photoresist layer is selectively exposed to actinic radiation. The selectively exposed photoresist layer is developed to form a pattern in the photoresist layer.

### BACKGROUND

The semiconductor integrated circuit (IC) industry has experienced rapid growth. Technological advances in IC materials and design have produced generations of ICs where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs. For continued advances to be realized, similar developments in IC processing and manufacturing are needed. However, as the size of individual devices has decreased, process windows for photolithographic processing has become tighter and tighter. As such, advances in the field of photolithographic processing are necessary to maintain the ability to scale down the devices, and further improvements are needed in order to meet the desired design criteria such that the march towards smaller and smaller components may be maintained.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a process flow of manufacturing a semiconductor device according to embodiments of the disclosure.

FIG. 2 shows a process stage of a sequential operation according to an embodiment of the disclosure.

FIGS. 3A and 3B show ligands according to embodiments of the disclosure.

FIG. 4 shows ligands according to embodiments of the disclosure.

FIGS. 5A and 5B show ligands according to embodiments of the disclosure.

FIGS. 6A, 6B, and 6C show ligands according to embodiments of the disclosure.

FIG. 7 shows ligands according to embodiments of the disclosure.

FIGS. 8A and 8B show a process stage of a sequential operation according to an embodiment of the disclosure.

FIG. 9 shows a process stage of a sequential operation according to embodiments of the disclosure.

FIG. 10 shows a process stage of a sequential operation according to embodiments of the disclosure.

FIGS. 11A and 11B show a process stage of a sequential operation according to an embodiment of the disclosure.

FIG. 12 shows a process stage of a sequential operation according to embodiments of the disclosure.

FIG. 13 shows a process stage of a sequential operation according to embodiments of the disclosure.

FIG. 14 shows a process stage of a sequential operation according to embodiments of the disclosure.

FIG. 15 shows a process stage of a sequential operation according to embodiments of the disclosure.

FIGS. 16A and 16B show organometallic precursors according to embodiments of the disclosure. FIG. 16C shows a reaction the organometallic precursors undergo when exposed to actinic radiation. FIG. 16D shows examples of organometallic precursors according to embodiments of the disclosure.

FIG. 17 illustrates a deposition apparatus according to embodiments of the disclosure.

FIG. 18 shows a process stage of a sequential operation according to an embodiment of the disclosure.

FIGS. 19A and 19B show a process stage of a sequential operation according to embodiments of the disclosure.

FIG. 20 shows a process stage of a sequential operation according to an embodiment of the disclosure.

FIG. 21 shows a process stage of a sequential operation according to an embodiment of the disclosure.

FIGS. 22A and 22B show a process stage of a sequential operation according to embodiments of the disclosure.

FIG. 23 shows a process stage of a sequential operation according to embodiments of the disclosure.

FIG. 24 shows a process stage of a sequential operation according to embodiments of the disclosure.

FIG. 25 shows a process stage of a sequential operation according to embodiments of the disclosure.

FIG. 26 shows a process stage of a sequential operation according to embodiments of the disclosure.

FIGS. 27A and 27B show a process stage of a sequential operation according to embodiments of the disclosure.

FIGS. 28A and 28B show a process stage of a sequential operation according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper,” “top,” “bottom,” “middle,” and the like, may be used herein for ease of description to describe one element or feature's relationship to another element(s) or feature(s) as illustrated in the figures, and do not preclude additional structures above or below or between the stated feature. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations between the described operations, and the order of operations may be changed. In the present disclosure, a phrase “one of A, B and C” means “A, B and/or C (A, B, C, A and B, A and C, B and C, or A, B and C), and does not mean one element from A, one element from B and one element from C, unless otherwise described. In the following embodiments, materials, configurations, dimensions, processes and/or operations as described with respect to one embodiment (e.g., one or more figures) may be employed in the other embodiments, and detailed description thereof may be omitted.

To achieve smaller feature sizes and feature spacing in semiconductor devices improved etching resistance of the photoresist pattern is desirable. Embodiments of this disclosure provide improved etch resistance of the photoresist pattern during patterning of an underlying substrate or target layer. Embodiments of this disclosure provide improved integrity of the photoresist pattern and decreased line width roughness and line edge roughness, and scum reduction. Embodiments of the disclosure allow reduced exposure doses.

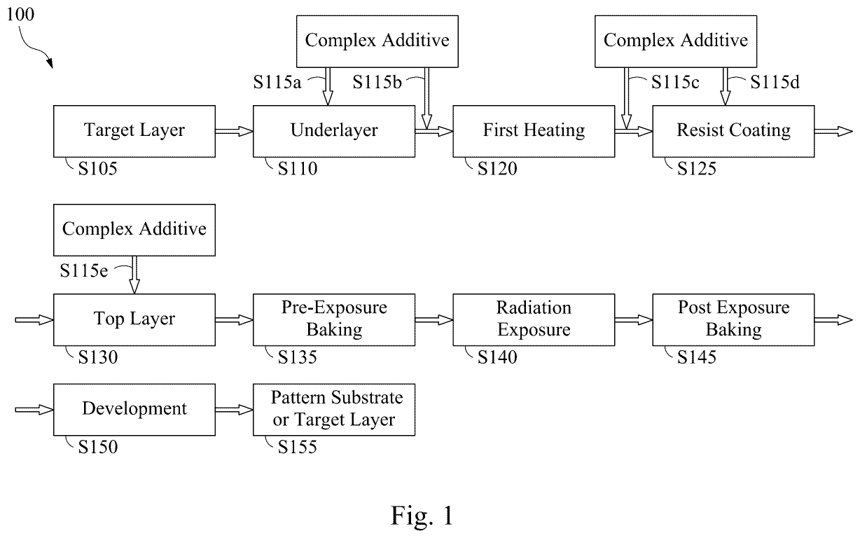

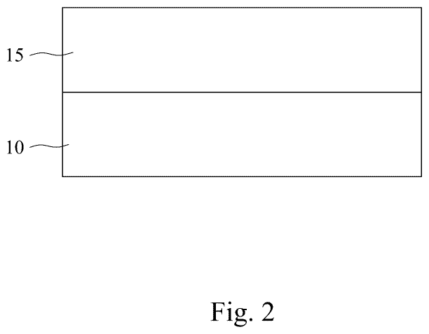

FIG. 1 illustrates a flowchart of methods 100 for semiconductor device fabrication in accordance with some embodiments. FIGS. 2, 8A-15, and 18-28B illustrate sectional views of a semiconductor device at various fabrication stages in accordance with some embodiments. The methods 100 and systems utilized in the methods are collectively described with reference to these figures.

The method 100 includes an operation S105 of forming a target layer 60 over a substrate 10 in some embodiments. In some embodiments, the substrate 10 is a semiconductor substrate. In some embodiments, the semiconductor substrate 10 is a semiconductor wafer, such as a silicon wafer. In some embodiments, the target layer 60 is an insulating layer, in other embodiments, the target layer 60 is a semiconductor layer, and in other embodiments, the target layer 60 is a conductive layer.

In some embodiments, a resist underlayer 20 is formed over the substrate 10 or the target layer 60 in operation S110. A metal complex is added to the underlayer composition in some embodiments and then the underlayer/metal complex composition is deposited over the target layer 60 or the substrate 10 in operation S115a to form the underlayer 20. In some embodiments, the metal complex is deposited over the underlayer 20 in operation S115b. In some embodiments, metal complex is mixed with a solvent and deposited over the underlayer 20.

In some embodiments, the underlayer 20, undergoes a first heating operation S120 to dry and cure the underlayer 20. The underlayer may be heated at a temperature ranging from about 40 °C to about 150 °C for a time sufficient to cure or dry the underlayer 20. The heating may occur before the metal complex is deposited over the underlayer.

In some embodiments, the metal complex is deposited in operation S115c over the underlayer after the first heating operation S120. The metal complex may be mixed with a suitable solvent and deposited over the underlayer. A resist layer composition is subsequently coated on a surface of the substrate 10, target layer 60, or underlayer 20 in operation S125, in some embodiments, to form a resist layer 15, as shown in FIG. 2. In some embodiments, the resist layer 15 is a photoresist layer. The resist layer 15 is formed over a layer including the metal complex in some embodiments. In other embodiments, the metal complex is added to the resist composition in operation S115d before the resist composition is coated over the substrate 10, target layer 60, or the underlayer 20. In other embodiments, the metal complex is mixed with a top layer composition and deposited as a top layer 130 over the resist layer 15 in operation S130. In other embodiments, the metal complex is added to the top layer 130 after the top layer composition is formed over the resist layer 15 in operation S115e.

A first metal complex can be disposed over the substrate, the target layer, or the underlayer by mixing the first metal complex with a solvent, the underlayer composition, or the photoresist composition and then applying by any suitable technique including spin coating, chemical vapor deposition, physical vapor deposition, atomic layer deposition, spray misting, or by a gas/liquid/solid chemical treatment. In some embodiments, a chemical vapor treatment for applying the first metal complex includes mixing the first metal complex with water, oxygen, nitrogen, carbon dioxide, ozone, or ammonia.

Then the resist layer 15 undergoes a second heating operation S135 (or pre-exposure baking operation) to evaporate solvents in the resist composition or cure the resist layer in some embodiments. The resist layer 15 is baked at a temperature and time sufficient to cure and dry the photoresist layer 15. In some embodiments, the resist layer is heated at a temperature of about 40 °C to about 150 °C for about 10 seconds to about 10 minutes. The pre-exposure baking S135 may also cause the first metal complex to diffuse throughout the resist layer 15. The pre-exposure baking causes the first metal complex to diffuse from the underlayer 20 into and throughout the resist layer in some embodiments, and causes the first metal complex to diffuse from the top layer 130 into and throughout the resist layer 15 in some other embodiments.

In some embodiments, the metal complex is a first metal complex represented by a structure: M-Rₚ, where M is a first metal, R is a ligand, and 5≤p≤12. In some embodiments, the first metal is at least one selected from the group consisting of Ag, Cd, In, Sn, Sb, Te, Cs, Au, Hg, Tl, Pb, Bi, Po, At, W, Zn, and Ti. In some embodiments, R is at least one of hydrogen; an alkene group; an alkyne group; a styryl group; an acrylate group; a methacrylate group; a cinnamate group a branched or unbranched, cyclical, or non-cyclical C1-C20 alkyl group; a C6-C20 aryl group; a C7-C20 aralkyl group; an epoxy group; an oxetane group; a primary amino group; a secondary amino group; a tertiary amino group; or an alkoxy group. In some embodiments, the first metal complex includes a plurality of metal complex molecules and each metal complex molecule comprises 5 to 12 crosslinking sites.

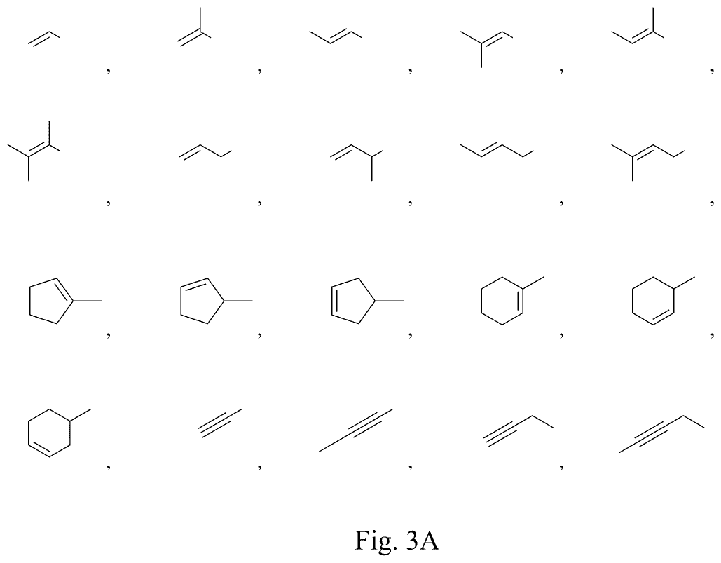

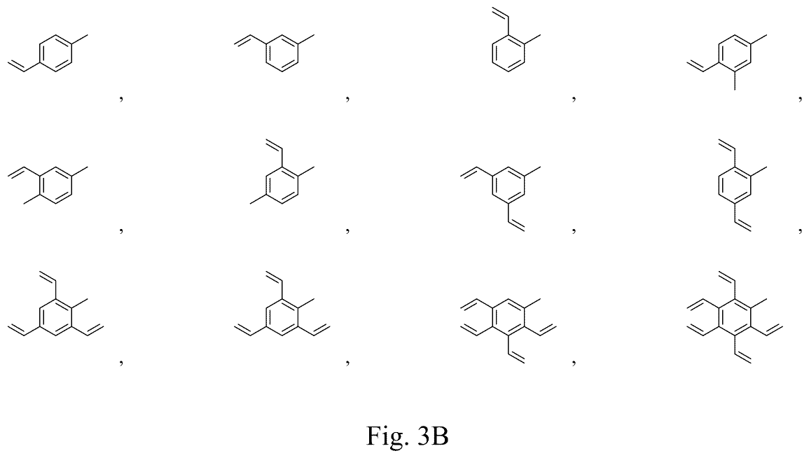

In some embodiments, the ligand R is at least one selected from the group of alkene and alkyne groups shown in FIG. 3A. In some embodiments, R is at least one selected from the group of styryl groups shown in FIG. 3B.

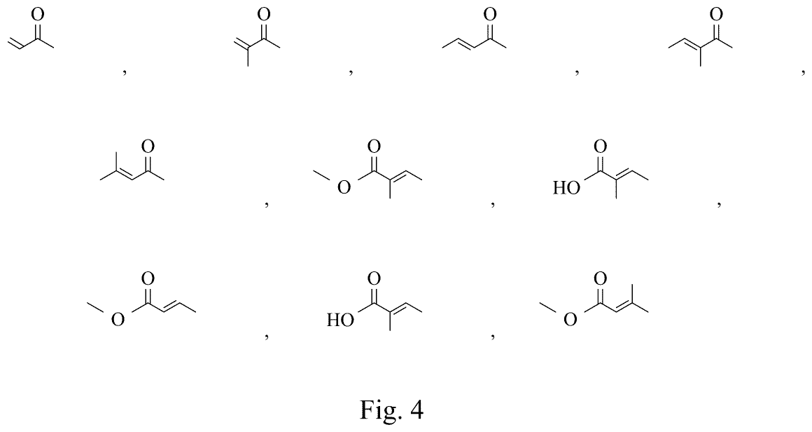

In some embodiments, the ligand R is at least one selected from the group of acrylate and methacrylate groups shown in FIG. 4. In some embodiments, the ligand R is substituted with at least one oxygen, nitrogen, or halogen containing group, The halogens include F, Cl, Br, and I. In some embodiments, the oxygen containing group is a carbonyl group or a C1-C9 alkoxy group. In some embodiments, the nitrogen containing group includes primary, secondary, or tertiary amino groups. In some embodiments, the amino groups include C1-C9 alkyl groups. In some embodiments, R is a ring shaped group and the ring includes an oxygen or nitrogen atom in the ring structure.

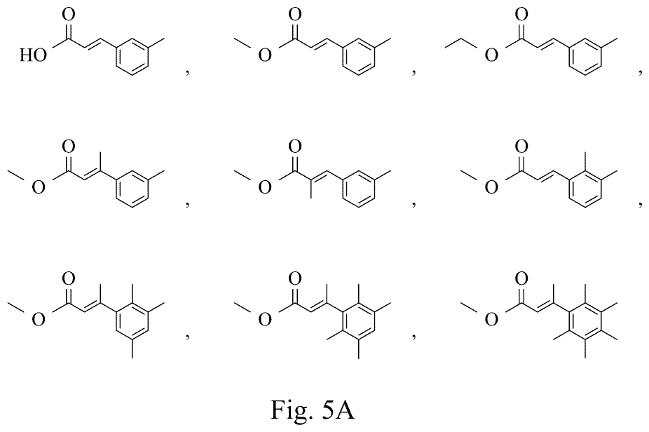

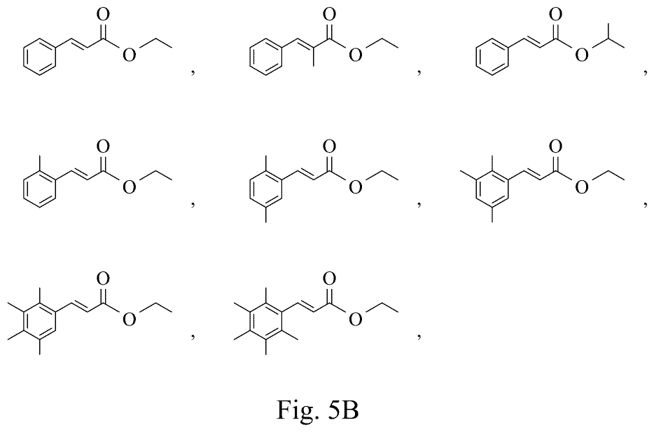

In some embodiments, the ligand R is at least one selected from the group of cinnamate groups shown in FIGS. 5A and 5B. In some embodiments, R is substituted with a nitrogen, oxygen, or halogen containing group on a phenyl group. The halogens include F, Cl, Br, and I. In some embodiments, the oxygen containing group is a carbonyl group or a C1-C9 alkoxy group. In some embodiments, the nitrogen containing group includes primary, secondary, or tertiary amino groups. In some embodiments, the amino groups include C1-C9 alkyl groups. In some embodiments, R is a ring shaped group and the ring includes an oxygen or nitrogen atom in the ring structure.

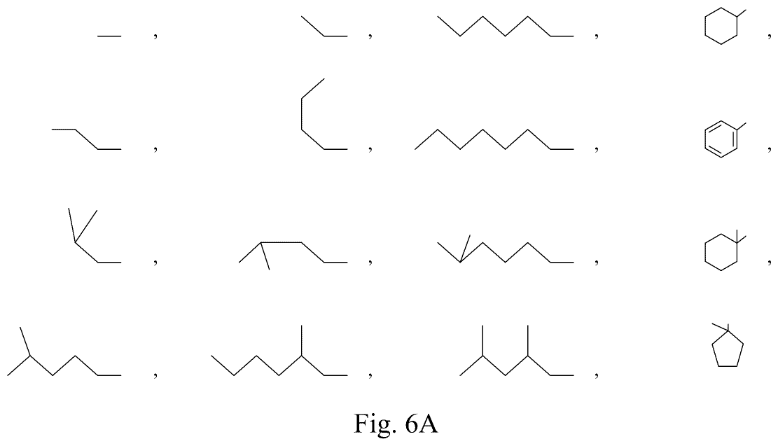

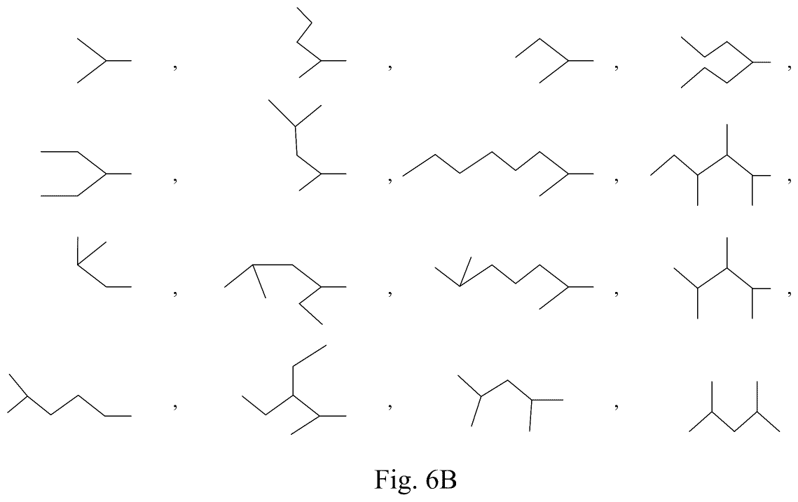

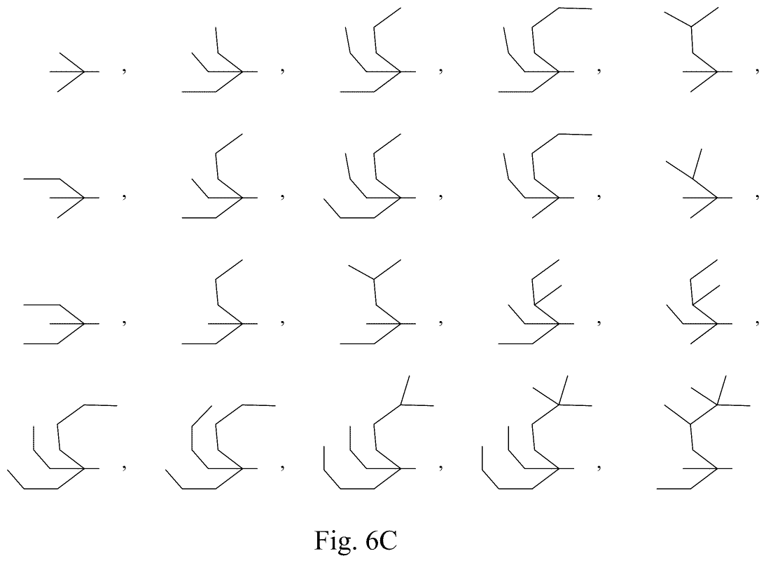

In some embodiments, the ligand R is at least one selected from the C1-C20 structures shown in FIGS. 6A, 6B, and 6C. The C1-C20 structures may be unbranched or branched, cyclic or noncyclic, saturated or unsaturated. In some embodiments, R is substituted with a nitrogen, oxygen, or halogen containing group. The halogens include F, Cl, Br, and I. In some embodiments, the oxygen containing group is a carbonyl group or a C1-C9 alkoxy group. In some embodiments, the nitrogen containing group includes primary, secondary, or tertiary amino groups. In some embodiments, the amino groups include C1-C9 alkyl groups. In some embodiments, R is a ring shaped group and the ring includes an oxygen or nitrogen atom in the ring structure.

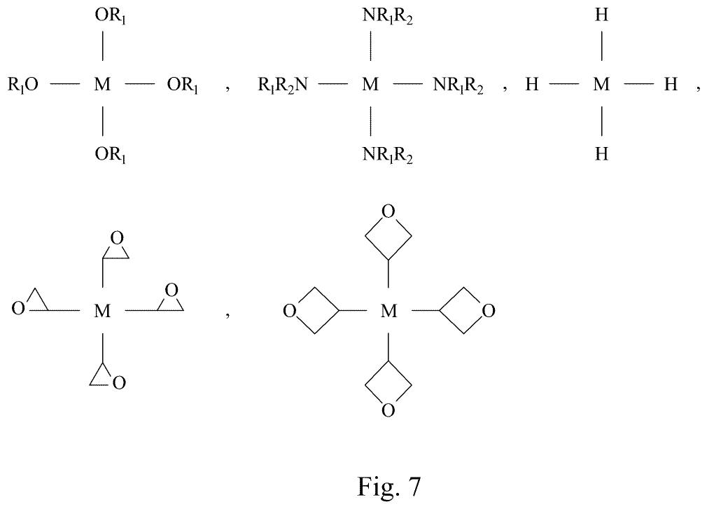

In some embodiments, the first metal complex includes one of the structures shown in FIG. 7. R₁ and R₂ may be a hydrogen or a C1-C20 structure, and M is at least one of Ag, Cd, In, Sb, Te, Cs, Au, Hg, Tl, Pb, Bi, Po, At, W, Zn, and Ti. The C1-C20 may be unbranched or branched, cyclic or noncyclic, saturated or unsaturated. In some embodiments, R₁ and R₂ are substituted with a halogen including F, Cl, Br, and I. In some embodiments, the metal complexes in FIG. 7 are thermally sensitive, and react with the resist composition during one of the heating operations. In some embodiments, the first metal complexes crosslink with the resist composition when the photoresist layer 15 is heated at a temperature of from about 40 °C to about 400 °C for about 20 seconds to about 1500 seconds. In other embodiments, the photoresist layer 15 is heated at a temperature ranging from about 50 °C to about 250 °C for about 50 seconds to about 1000 seconds to react the metal complex structures in FIG. 7 with the photoresist layer. At heating temperatures and times below the disclosed ranges there may be insufficient crosslinking. At heating temperatures and times greater than the disclosed ranges the resist layer or other layers may be damaged.

In some embodiments, the first metal complex includes any combination of the ligands shown in FIGS. 3A, 3B, 4, 5A, 5B, 6A, 6B, and 6C.

In an embodiment, the first metal complex composition includes a solvent. In some embodiments, the solvent is any suitable solvent. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), 2-heptanone (MAK), tetrahydrofuran (THF), and isobutyl propionate.

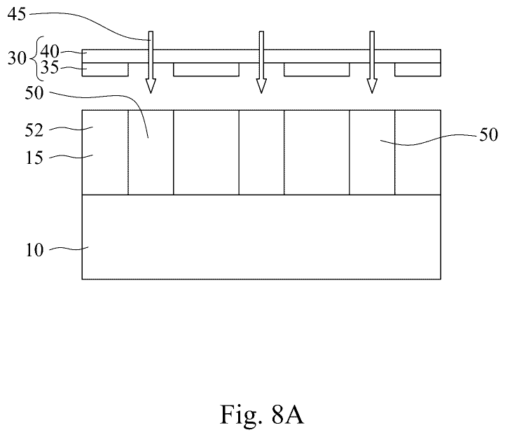

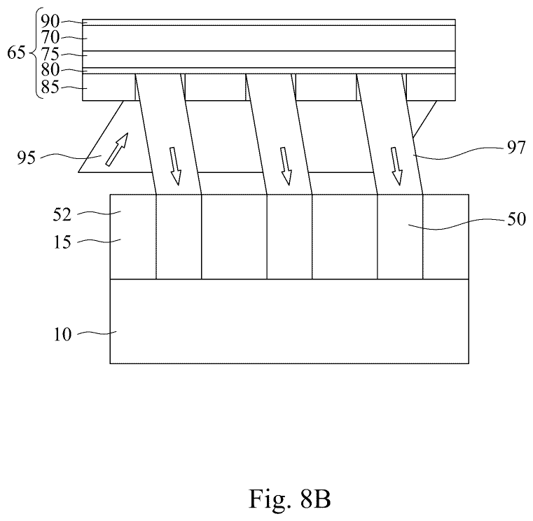

After the second (or pre-exposure) heating operation S135 of the photoresist layer 15, the photoresist layer 15 is selectively exposed to actinic radiation 45/97 (see FIGS. 8A and 8B) in operation S140. In some embodiments, the radiation is electromagnetic radiation, such as g-line (436 nm wavelength), i-line (365 nm wavelength), ultraviolet radiation, deep ultraviolet radiation, extreme ultraviolet radiation, or electron beam, or the like. In some embodiments, the radiation source is selected from the group consisting of a mercury vapor lamp, xenon lamp, carbon arc lamp, a KrF excimer laser light (248 nm wavelength), an ArF excimer laser light (193 nm wavelength), an F₂ excimer laser light (157 nm wavelength), or a CO₂ laser-excited Sn plasma (extreme ultraviolet, 13.5 nm wavelength).

As shown in FIG. 8A, the exposure radiation 45 passes through a photomask 30 before irradiating the photoresist layer 15 in some embodiments. In some embodiments, the photomask has a pattern to be replicated in the photoresist layer 15. The pattern is formed by an opaque pattern 35 on the photomask substrate 40, in some embodiments. The opaque pattern 35 may be formed by a material opaque to ultraviolet radiation, such as chromium, while the photomask substrate 40 is formed of a material that is transparent to ultraviolet radiation, such as fused quartz.

In some embodiments, the selective exposure of the photoresist layer 15 to form exposed regions 50 and unexposed regions 52 is performed using extreme ultraviolet lithography. In some embodiments of an extreme ultraviolet lithography operation, a reflective photomask 65 is used to form the patterned exposure light in some embodiments, as shown in FIG. 8B. The reflective photomask 65 includes a low thermal expansion glass substrate 70, on which a reflective multilayer 75 of Si and Mo is formed. A capping layer 80 and absorber layer 85 are formed on the reflective multilayer 75. A rear conductive layer 90 is formed on the back side of the low thermal expansion glass substrate 70. In extreme ultraviolet lithography, extreme ultraviolet radiation 95 is directed towards the reflective photomask 65 at an incident angle of about 6°. A portion 97 of the extreme ultraviolet radiation is reflected by the Si/Mo multilayer 75 towards the photoresist coated substrate 10, while the portion of the extreme ultraviolet radiation incident upon the absorber layer 85 is absorbed by the photomask. In some embodiments, additional optics, including mirrors, are between the reflective photomask 65 and the photoresist coated substrate.

The region of the photoresist layer exposed to radiation 50 undergoes a chemical reaction thereby changing its solubility in a subsequently applied developer relative to the region of the photoresist layer not exposed to radiation 52. In some embodiments, the portion of the photoresist layer exposed to radiation 50 undergoes a crosslinking reaction.

The amount of electromagnetic radiation can be characterized by a fluence or dose, which is obtained by the integrated radiative flux over the exposure time. Suitable radiation fluences range from about 1 mJ/cm² to about 150 mJ/cm² in some embodiments, from about 2 mJ/cm² to about 100 mJ/cm² in other embodiments, and from about 3 mJ/cm² to about 50 mJ/cm² in other embodiments. A person of ordinary skill in the art will recognize that additional ranges of radiation fluences within the explicit ranges above are contemplated and are within the present disclosure.

In some embodiments, the selective or patternwise exposure is performed by a scanning electron beam. With electron beam lithography, the electron beam induces secondary electrons, which modify the irradiated material. High resolution is achievable using electron beam lithography and the metal-containing resists disclosed herein. Electron beams can be characterized by the energy of the beam, and suitable energies range from about 5 V to about 200 kV (kilovolt) in some embodiments, and from about 7.5 V to about 100 kV in other embodiments. Proximity-corrected beam doses at 30 kV range from about 0.1 μC/cm² to about 100 μC/cm² in some embodiments, from about 0.5 μC/cm² to about 25 μC/cm² in other embodiments, and in other embodiments from about 1 μC/cm² to about 5 μC/cm². A person of ordinary skill in the art can compute corresponding doses at other beam energies based on the teachings herein and will recognize that additional ranges of electron beam properties within the explicit ranges above are contemplated and are within the present disclosure.

Next, the photoresist layer 15 undergoes a third heating (or post-exposure bake (PEB)) in operation S145. In some embodiments, the photoresist layer 15 is heated at a temperature of about 40 °C to about 400 °C for about 20 seconds to about 1500 seconds. In other embodiments, the photoresist layer 15 is heated at a temperature ranging from about 50 °C to about 250 °C for about 50 seconds to about 1000 seconds. The post-exposure baking assists in crosslinking the radiation exposed photoresist in some embodiments. In some embodiments, the post-exposure baking assists in generating, dispersing, and reacting chemical reactants formed during the actinic radiation exposure, including acids or bases generated by the action of the actinic radiation. The PEB helps to create or enhance chemical reactions, which generate chemical differences between the exposed region 50 and the unexposed region 52 within the photoresist layer. At heating temperatures and times below the disclosed ranges there may be insufficient generating, dispersing, and reacting of the chemical reactants formed during the actinic radiation exposure. There may also be insufficient activation of the thermally sensitive metal complexes, and thus insufficient crosslinking. At heating temperatures and times greater than the disclosed ranges the resist layer or other layers may be damaged.

In some embodiments, the PEB causes thermally sensitive first metal complexes to crosslink with the photoresist layer 15. In some embodiments, the PEB is performed in heating chamber 110, as shown in FIG. 9. In some embodiments, a heating element in the wafer stage 115 heats the photoresist layer. In some embodiments, the photoresist layer is heated using a hot plate.

In some embodiments, the first metal complex is sensitive to ultrasonic energy. In some embodiments, after selectively exposing the photoresist layer to actinic radiation, the photoresist-coated substrate is placed in an ultrasonic apparatus 120 and ultrasonic energy 125 is applied to initiate or advance the crosslinking of the first metal complex and the photoresist layer before developing the selectively exposed photoresist layer.

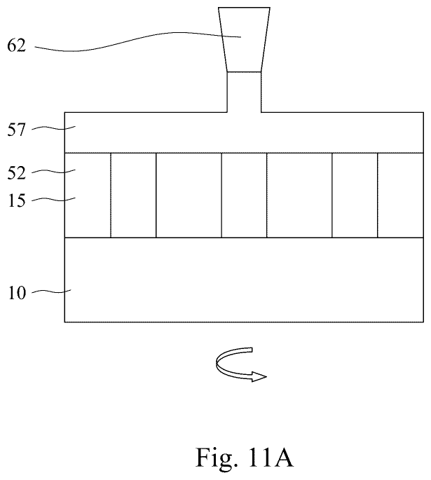

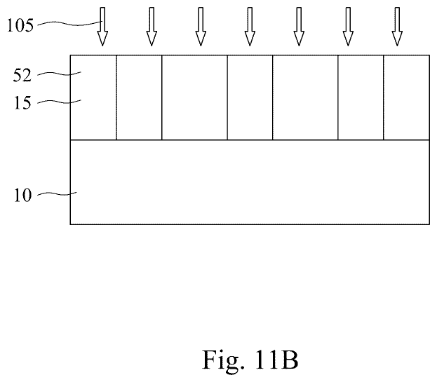

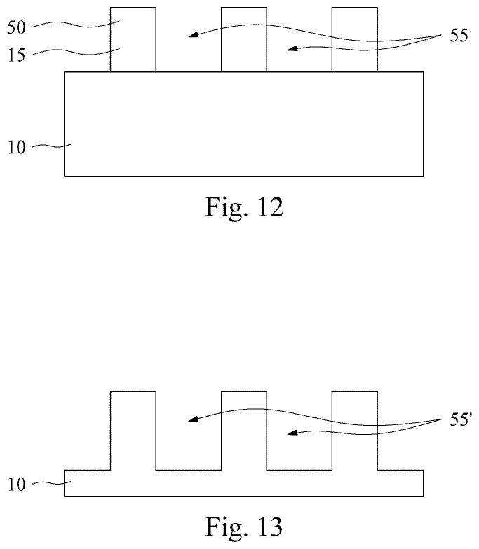

The selectively exposed photoresist layer is subsequently developed by applying a developer to the selectively exposed photoresist layer in operation S150. As shown in FIG. 11A, a developer 57 is supplied from a dispenser 62 to the photoresist layer 15. In some embodiments, the developer 105 is a dry developer, as shown in FIG. 11B. In some embodiments, the unexposed region 52 of the photoresist layer is removed by the developer 57, 105 forming a pattern of openings 55 in the photoresist layer 15 exposing portions of the substrate 10, as shown in FIG. 12.

In some embodiments, the photoresist developer 57 includes a solvent, and an acid or a base. In some embodiments, the concentration of the solvent is from about 60 wt. % to about 99 wt. % based on the total weight of the photoresist developer. The acid or base concentration is from about 0.001 wt. % to about 20 wt. % based on the total weight of the photoresist developer. In certain embodiments, the acid or base concentration in the developer is from about 0.01 wt. % to about 15 wt. % based on the total weight of the photoresist developer.

In some embodiments, the developer 57 is applied to the photoresist layer 15 using a spin-on process. In the spin-on process, the developer 57 is applied to the photoresist layer 15 from above the photoresist layer 15 while the photoresist-coated substrate is rotated, as shown in FIG. 11A. In some embodiments, the developer 57 is supplied at a rate of between about 5 ml/min and about 800 ml/min, while the photoresist coated substrate 10 is rotated at a speed of between about 100 rpm and about 2000 rpm. In some embodiments, the developer is at a temperature of between about 10 °C and about 80 °C during the development operation. The development operation continues for between about 30 seconds to about 10 minutes in some embodiments.

In some embodiments, the developer 57 includes an organic solvent. The organic solvent can be any suitable solvent. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, 4-methyl-2-pentanol, acetone, methyl ethyl ketone, dimethylformamide (DMF), isopropanol (IPA), tetrahydrofuran (THF), methyl isobutyl carbinol (MIBC), n-butyl acetate (nBA), 2-heptanone (M A K), tetrahydrofuran (THF), and dioxane.

While the spin-on operation is one suitable method for developing the photoresist layer 15 after exposure, it is intended to be illustrative and is not intended to limit the embodiment. Rather, any suitable development operations, including dip processes, puddle processes, and spray-on methods, may alternatively be used. All such development operations are included within the scope of the embodiments.

In some embodiments, a dry developer 105 is applied to the selectively exposed photoresist layer 15, as shown in FIG. 11B. In some embodiments, the dry developer 105 is a plasma or chemical vapor, and the dry development operation S150 is a plasma etching or chemical etching operation. The dry development uses the differences related to the composition, extent of cross-linking, and film density to selectively remove the desired portions of the resist. In some embodiments, the dry development processes uses either a gentle plasma (high pressure, low power) or a thermal process in a heated vacuum chamber while flowing a dry development chemistry, such as H₂, Cl₂, CHCl₃, CH₂Cl₂, CH₄, CH₃F, CH₂F₂, CHF₃CF₄, N₂, SO₂, BF₃, BCl₃, CCl₄, HCl, O₂, NF₃, NH₃, N₂H₂, Br₂, HBr, and NO₂, or other Lewis Acid in the vapor state. In some embodiments, the developer 105 removes the unexposed material, leaving behind a pattern of the exposed film that is transferred into the underlying layers by plasma-based etch processes.

In some embodiments, the dry development includes plasma processes, including transformer coupled plasma (TCP), inductively coupled plasma (ICP) or capacitively coupled plasma (CCP). In some embodiments, the plasma process is conducted at a pressure ranging from about 5 mTorr to about 20 mTorr, at a power level from about 250 W to about 1000 W, at a temperature ranging from about 0 °C to about 300 °C, and at flow rate of about 100 to about 1000 sccm, for about 1 to about 3000 seconds.

In some embodiments, the dry development reaction is as follows:
MOₓC_{y}+HX→MₓC_{y}+H₂O; where MOₓC_{y} is the photoresist, HX is the developer gas, and MₓC_{y} is the development product, which is a gas at low pressure.

In some embodiments, the pattern of openings 55 in the photoresist layer 15 is extended into the substrate 10, or target layer 60 (see FIG. 24) in operation S150 to create a pattern of openings 55′ in the substrate 10 or target layer 60, thereby transferring the pattern in the photoresist layer 15 into the substrate 10 or target layer 60, as shown in FIGS. 13 and 24. The pattern is extended into the substrate or target layer by etching, using one or more suitable etchants. In some embodiments, the patterned photoresist layer pattern 15 is at least partially removed during the etching operation. In some embodiments, the patterned photoresist layer 15 is removed after etching the substrate 10 or target layer by using a suitable photoresist stripper solvent or by a photoresist ashing operation.

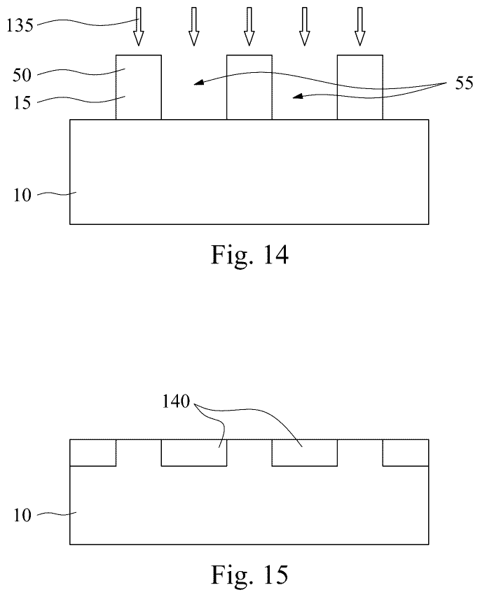

In some embodiments, the patterned photoresist layer 15 is used as a mask in an ion implantation operation. As shown in FIG. 14, the ions 135 are implanted into the substrate 10 using a suitable ion implantation apparatus or technique. After forming ion implanted regions 140, the patterned photoresist layer 15 is removed as shown in FIG. 15. A suitable photoresist stripping or plasma ashing operation is used to remove the patterned photoresist layer after the implantation operation.

In some embodiments, the substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate 10 is a silicon layer of an SOI (silicon-on insulator) substrate. In certain embodiments, the substrate 10 is made of crystalline Si.

The substrate 10 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate 10. The germanium concentration of the SiGe buffer layers may increase from 30 atomic % for the bottom-most buffer layer to 70 atomic % for the top-most buffer layer.

In some embodiments, the substrate 10 includes one or more layers of at least one metal, metal alloy, and metal nitride/sulfide/oxide/silicide having the formula MXₐ, where M is a metal and X is N, S, Se, O, Si, and a is from about 0.4 to about 2.5. In some embodiments, the substrate 10 includes titanium, aluminum, cobalt, ruthenium, titanium nitride, tungsten nitride, tantalum nitride, and combinations thereof.

In some embodiments, the substrate 10 includes a dielectric having at least a silicon or metal oxide or nitride of the formula MX_{b}, where M is a metal or Si, X is N or O, and b ranges from about 0.4 to about 2.5. In some embodiments, the substrate 10 includes silicon dioxide, silicon nitride, aluminum oxide, hafnium oxide, lanthanum oxide, and combinations thereof.

The photoresist layer 15 is a photosensitive layer that is patterned by exposure to actinic radiation. Typically, the chemical properties of the photoresist regions struck by incident radiation change in a manner that depends on the type of photoresist used. Photoresist layers 15 are either positive tone resists or negative tone resists. A positive tone resist refers to a photoresist material that when developed, the portions of the photoresist layer exposed to actinic radiation, such as UV light, are removed, while the region of the photoresist that is non-exposed (or exposed less) remains on the substrate after the development operation. A negative tone resist, on the other hand, refers to a photoresist material that when developed, the portions of the photoresist exposed to actinic radiation remain on the substrate after the development operation, while the region of the photoresist that is non-exposed (or exposed less) is removed during the development operation.

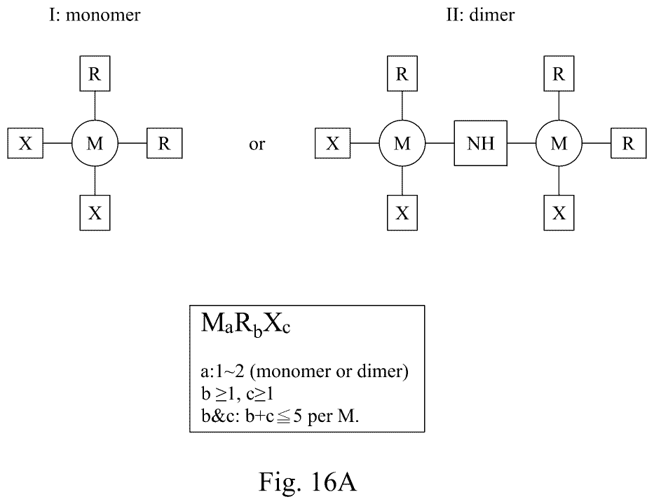

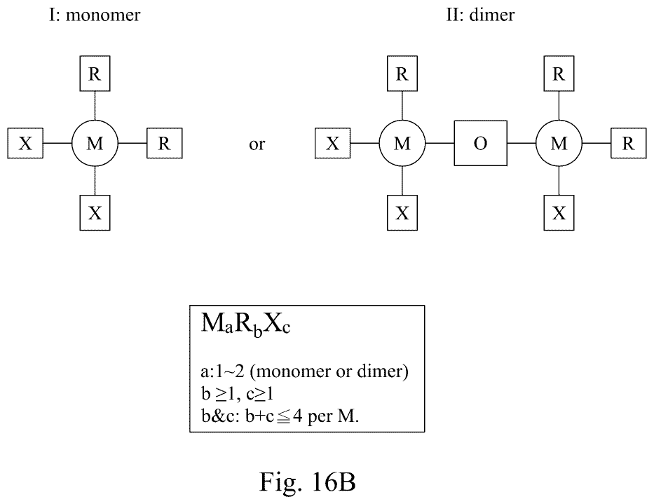

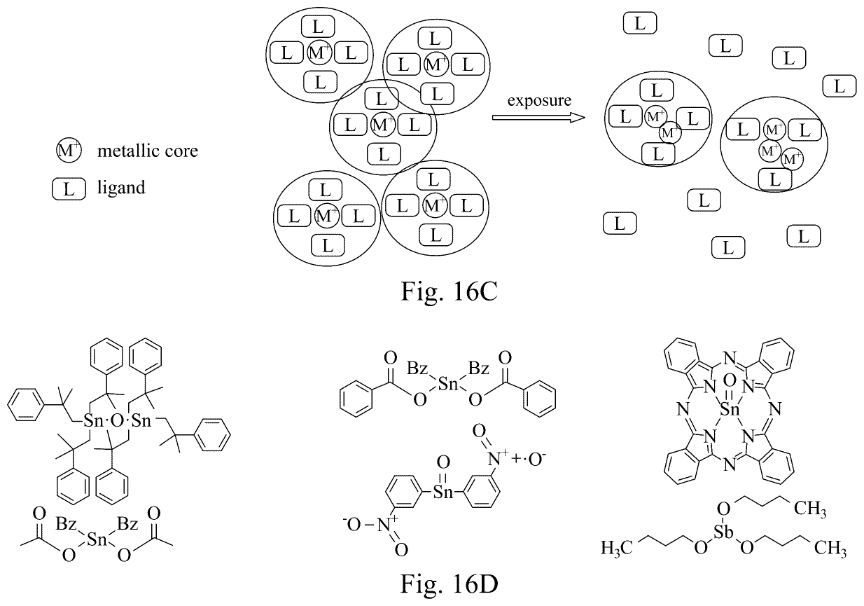

In some embodiments, the photoresist layer 15 is made of a photoresist composition, including a first compound or a first precursor and a second compound or a second precursor combined in a vapor state. In some embodiments, the first precursor or first compound is a second metal complex including a second metal. In some embodiments, the second metal is different from the first metal of the first metal complex previously described herein. In some embodiments, the first metal complex and the second metal complex are made of different materials. In some embodiments, the first precursor or first compound is an organometallic complex having a formula: MₐR_{b}X_{c} (a, b and c are natural number), as shown in FIGS. 16A and 16B, where M is one or more selected from the group consisting of Sn, Bi, Sb, In, Te, and oxides thereof; R is a substituted or unsubstituted alkyl, alkenyl, or carboxylate group. In some embodiments, X is a ligand, ion, or other substituent, which is reactive with the second compound or second precursor; and 1≤a≤2, b≥1, c≥1, and b+c≤5. In certain embodiments, b+c=4. In some embodiments, the alkyl, alkenyl, or carboxylate group is substituted with one or more fluoro groups. In some embodiments, the organometallic precursor is a dimer, as shown in FIG. 16A, where each monomer unit is linked by an amine group. In some embodiments, b=c=2. In other embodiments, the organometallic precursor is a dimer, as shown in FIG. 16B, where each monomer unit is linked by oxygen. In some embodiments, b=1 and c=3. Each monomer has a formula: MₐR_{b}X_{c}, as defined above.

In some embodiments, R in the formula MₐR_{b}X_{c} includes alkyl groups that are substituted by different electron-donating groups (EDG) and/or electron-withdrawing groups (EWG) to tune the bond dissociation energy to provide a bond that is cleaved by a low EUV dosage. In some embodiments, R is a substituted or unsubstituted C₁-C₂₀ alkyl group, including all isomers of C1-C20 alkyl groups. The EDG include oxido group (—O⁻), amino groups (—NH₂, —NHR, —NR₂, where R=C1-C4 groups and phenyl groups), hydroxyl and alkoxyl groups (—OH, —OR, where R=C1-C4 groups, and phenyl groups), acylamido groups (—NHCOR, where R=C1-C4 groups and phenyl groups), alkylthio and sulfhydryl groups (—SH, —SR, where R=C1-C4 groups and phenyl groups), phenyl group, and carboxylate groups (—(C═O)O—). The EWG include halogens (—I, —Cl, —Br, —F), ammonium groups (—NR₃⁺, where R=C1-C4 groups and phenyl groups), nitro groups (—NO₂), sulfonic acids and sulfonyl groups (—SO₃H, —SO₂R, where R=C1-C4 groups and phenyl groups), cyano group (—CN), formyl and acyl groups (—CHO, —COR, where R=C1-C4 groups and phenyl groups), carboxyl and alkoxycarbonyl groups (—CO₂H, —CO₂R, where R=C1-C4 groups and phenyl groups), and aminocarbonyl groups (—CONH₂, —CONHR, —CONR, where R=C1-C4 groups and phenyl groups), where the C1-C4 groups include all isomers of the C1-C4 groups.

In some embodiments of the first precursor or compound having the formula MₐR_{b}X_{c}, R includes all structural isomers of C1-C4 alkyl groups substituted with a phenyl group, an amino group (—NH₂, —NHR, —NR₂, where R=C1-C3 alkyl group), hydroxyl and alkoxyl groups (—OH, —OR, where R=C1-C3 alkyl group and a phenyl group). In some embodiments of the first precursor or compound having the formula MₐR_{b}X_{c}, R includes C1-C4 alkyl groups substituted at the α-C position by one or two phenyl groups, an amino group (—NH₂, —NHR, —NR₂, where R=C1, C2 or C3 alkyl group), and alkoxyl groups (—OR, where R=C1, C2 or C3 alkyl group).

In some embodiments, X is any substituent readily displaced by the second compound or second precursor to generate an M-OH group, such as a group selected from amines, including dialkylamino and monoalkylamino; alkoxy; carboxylates, halogens, and sulfonates. In some embodiments, the sulfonate group is substituted with one or more amine groups. In some embodiments, the halogen is one or more selected from the group consisting of F, Cl, Br, and I. In some embodiments, the sulfonate group includes a substituted or unsubstituted C1-C3 group.

In some embodiments, R in the formula MₐR_{b}X_{c} includes a C7-C11 aralkyl group, such as a benzyl group, an ethylbenzyl group, a propylbenzyl group, an isopropylbenzyl group, a butylbenzyl group, a sec-butylbenzyl group, or a tert-butylbenzyl group; a C3-C10 cycloalkyl group, such as a cyclobutyl group, a methyl cyclobutyl group, an ethyl cyclobutyl group, a cyclopentyl group, a methyl cyclopentyl, an ethyl cyclopentyl, a cyclohexyl group, a methyl cyclohexyl group, an ethyl cyclohexyl group, a cycloheptyl group, or a cyclooctyl group; a C2-C10 alkoxy group, such as a dimethyl ether group, a methyl dimethyl ether group, an ethyl methyl ether group, a diethyl ether group, a dipropyl ether group, a propyl ethyl ether group, a propyl methyl ether group, a diisopropyl ether group, an isopropyl ethyl ether group, or an isopropyl methyl ether group; or a C2-C10 alkylamino group, such as a methyl dimethyl amino group, a dimethylamino group, a diethylamino group, an ethyl dimethyl amino group, a dipropylamino group, a diisopropylamino group, an isopropyl methyl amino group, or an isopropyl ethyl amino group. In certain embodiments, R includes a cyclopentyl group, a benzyl group, a methyl ether group, an ethyl ether group, a secondary amino group, or a tertiary amino group.

In some embodiments, X in the formula MₐR_{b}X_{c} is a C2-C10 alkylamino group, such as a dimethylamino group, a diethylamino group, a dipropylamino group, a diisopropylamino group, a methyl ethyl amino group, a methyl propyl amino group, an ethyl propyl amino group, or a halogen, such as F, Cl, Br, or I. In some embodiments, X is a dimethylamino group or a diethylamino group, and c=3. In certain embodiments, M is Sn and a is 1. In some embodiments, 1≤a≤2, b≥1, c≥1, and b+c≤4. In some embodiments, b is 1, 2, or 3. In some embodiments, c is 1, 2, or 3. In certain embodiments, b+c=4, and in other embodiments b=1 and c=3.

In some embodiments, the first compound or first precursor includes one or more unsaturated bonds that can be coordinated with a functional group, such as a hydroxyl group, on the surface of the substrate or an intervening underlayer to improve adhesion of the photoresist layer to the substrate or underlayer.

In some embodiments, the second precursor or second compound is one or more selected from the group consisting of water, an amine, a borane, and a phosphine. In some embodiments, the amine has a formula NₚHₙXₘ, where 0≤n≤3, 0≤m≤3, n+m=3 when p is 1, and n+m=4 when p is 2, and each X is independently a halogen selected from the group consisting of F, Cl, Br, and I. In some embodiments, the borane has a formula BₚHₙXₘ, where 0≤n≤3, 0≤m≤3, n+m=3 when p is 1, and n+m=4 when p is 2, and each X is independently halogen selected from the group consisting of F, Cl, Br, and I. In some embodiments, the phosphine has a formula PₚHₙXₘ, where 0≤n≤3, 0≤m≤3, n+m=3, when p is 1, or n+m=4 when p is 2, and each X is independently halogen selected from the group consisting of F, Cl, Br, and I.

In some embodiments, the second precursor or compound is ammonia or hydrazine. The reaction product of the ammonia or hydrazine and the organometallic precursor or compound may form hydrogen bonds that increase the boiling point of the reaction product and prevent emission of the metal photoresist material, thereby preventing metal contamination. The hydrogen bonds can also help prevent moisture effects degrading the photoresist layer quality.

In some embodiments, the first organometallic compound or first organometallic precursor includes a metallic core M⁺ with ligands L attached to the metallic core M⁺, as shown in FIG. 16C. In some embodiments, the metallic core M⁺ is a metal oxide. The ligands L include C3-C12 aliphatic or aromatic groups in some embodiments. The aliphatic or aromatic groups may be unbranched or branched with cyclic, or noncyclic saturated pendant groups containing 1-9 carbons, including alkyl groups, alkenyl groups, and phenyl groups. The branched groups may be further substituted with oxygen or halogen. In some embodiments, the C3-C12 aliphatic or aromatic groups include heterocyclic groups. In some embodiments, the C3-C12 aliphatic or aromatic groups are attached to the metal by an ether or ester linkage. In some embodiments, the C3-C12 aliphatic or aromatic groups include nitrite and sulfonate substituents.

In some embodiments, the organometallic precursor or organometallic compound include a sec-hexyl tris(dimethylamino) tin, t-hexyl tris(dimethylamino) tin, i-hexyl tris(dimethylamino) tin, n-hexyl tris(dimethylamino) tin, sec-pentyl tris(dimethylamino) tin, t-pentyl tris(dimethylamino) tin, i-pentyl tris(dimethylamino) tin, n-pentyl tris(dimethylamino) tin, sec-butyl tris(dimethylamino) tin, t-butyl tris(dimethylamino) tin, i-butyl tris(dimethylamino) tin, n-butyl tris(dimethylamino) tin, sec-butyl tris(dimethylamino) tin, i-propyl(tris)dimethylamino tin, n-propyl tris(diethylamino) tin, and analogous alkyl(tris)(t-butoxy) tin compounds, including sec-hexyl tris(t-butoxy) tin, t-hexyl tris(t-butoxy) tin, i-hexyl tris(t-butoxy) tin, n-hexyl tris(t-butoxy) tin, sec-pentyl tris(t-butoxy), t-pentyl tris(t-butoxy) tin, i-pentyl tris(t-butoxy) tin, n-pentyl tris(t-butoxy) tin, t-butyl tris(t-butoxy) tin, i-butyl tris(butoxy) tin, n-butyl tris(butoxy) tin, sec-butyl tris(butoxy) tin, i-propyl(tris)dimethylamino tin, or n-propyl tris(butoxy) tin. In some embodiments, the organometallic precursors or organometallic compounds are fluorinated. In some embodiments, the organometallic precursors or compounds have a boiling point less than about 200 °C.

FIG. 16D shows examples of organometallic precursors according to embodiments of the disclosure. In FIG. 16D, Bz is a benzene group.

In some embodiments, the organometallic compound includes tin (Sn), antimony (Sb), bismuth (Bi), indium (In), tellurium (Te), and/or oxides thereof as the metal component, however, the disclosure is not limited to these metals. In other embodiments, additional suitable metals include titanium (Ti), zirconium (Zr), hafnium (Hf), vanadium (V), cobalt (Co), molybdenum (Mo), tungsten (W), aluminum (Al), gallium (Ga), silicon (Si), germanium (Ge), phosphorus (P), arsenic (As), yttrium (Y), lanthanum (La), cerium (Ce), lutetium (Lu), or oxides and combinations thereof. The additional metals can be as alternatives to or in addition to the Sn, Sb, Bi, In, and/or Te.

The particular metal used may significantly influence the absorption of radiation. Therefore, the metal component can be selected based on the desired radiation and absorption cross section. Tin, antimony, bismuth, tellurium, and indium provide strong absorption of extreme ultraviolet light at 13.5 nm. Hafnium provides good absorption of electron beam and extreme UV radiation. Metal compositions including titanium, vanadium, molybdenum, or tungsten have strong absorption at longer wavelengths, to provide, for example, sensitivity to 248 nm wavelength ultraviolet light.

In some embodiments, the operation S125 of depositing the photoresist composition is performed by a spin coating operation. In some embodiments, the operation S125 of depositing the photoresist composition is performed by a vapor phase deposition operation.

In some embodiments, the vapor phase deposition operation includes atomic layer deposition (ALD) or chemical vapor deposition (CVD). In some embodiments, the ALD includes plasma-enhanced atomic layer deposition (PE-ALD), and the CVD includes plasma-enhanced chemical vapor deposition (PE-CVD), metal-organic chemical vapor deposition (MO-CVD); atmospheric pressure chemical vapor deposition (AP-CVD), and low pressure chemical vapor deposition (LP-CVD). The depositing a photoresist layer includes combining the first compound or first precursor and the second compound or second precursor in a vapor state to form the photoresist composition. In some embodiments, the first compound or first precursor and the second compound or second precursor of the photoresist composition are introduced into the deposition chamber (CVD chamber) at about the same time. In some embodiments, the first compound or first precursor and second compound or second precursor are introduced into the deposition chamber (ALD chamber) in an alternating manner, i.e.—first one compound or precursor then a second compound or precursor, and then subsequently alternately repeating the introduction of the one compound or precursor followed by the second compound or precursor.

In some embodiments, the deposition chamber temperature ranges from about 30 °C to about 400 °C during the deposition operation, and between about 50 °C to about 250 °C in other embodiments. In some embodiments, the pressure in the deposition chamber ranges from about 5 mTorr to about 100 Torr during the deposition operation, and between about 100 mTorr to about 10 Torr in other embodiments. In some embodiments, the plasma power is less than about 1000 W. In some embodiments, the plasma power ranges from about 100 W to about 900 W. In some embodiments, the flow rate of the first compound or precursor and the second compound or precursor ranges from about 100 sccm to about 1000 sccm. In some embodiments, the ratio of the flow of the organometallic compound or precursor to the second compound or precursor ranges from about 1:1 to about 1:10 and ranges from about 1:3 to 1:6 in other embodiments. At operating parameters outside the above recited ranges, unsatisfactory photoresist layers result in some embodiments. In some embodiments, the photoresist layer formation occurs in a single chamber (a one-pot layer formation).

In a CVD process according to some embodiments of the disclosure, two or more gas streams, in separate inlet paths, of an organometallic precursor and a second precursor are introduced to the deposition chamber of a CVD apparatus, where they mix and react in the gas phase, to form a reaction product. The streams are introduced using separate injection inlets or a dual-plenum showerhead in some embodiments. The deposition apparatus is configured so that the streams of organometallic precursor and second precursor are mixed in the chamber, allowing the organometallic precursor and second precursor to react to form a reaction product. Without limiting the mechanism, function, or utility of the disclosure, it is believed that the product from the vapor-phase reaction becomes heavier in molecular weight, and is then condensed or otherwise deposited onto the substrate.

In some embodiments, an ALD process is used to deposit the photoresist layer. During ALD, a layer is grown on a substrate by exposing the surface of the substrate to alternate gaseous compounds (or precursors). In contrast to CVD, the precursors are introduced as a series of sequential, non-overlapping pulses. In each of these pulses the precursor molecules react with the surface in a self-limiting way, so that the reaction terminates once all the reactive sites on the surface are consumed. Consequently, the maximum amount of material deposited on the surface after a single exposure to all of the precursors (a so-called ALD cycle) is determined by the nature of the precursor-surface interaction.

In an embodiment of an ALD process, an organometallic precursor is pulsed to deliver the metal-containing precursor to the substrate surface in a first half reaction. In some embodiments, the organometallic precursor reacts with a suitable underlying species (for example OH or NH functionality on the surface of the substrate) to form a new self-saturating surface. Excess unused reactants and the reaction by-products are removed, by an evacuation-pump down and/or by a flowing an inert purge gas in some embodiments. Then, a second precursor, such as water or ammonia (NH₃), is pulsed to the deposition chamber in some embodiments. The water or NH₃ reacts with the organometallic precursor on the substrate to obtain a reaction product photoresist on the substrate surface. The second precursor also forms self-saturating bonds with the underlying reactive species to provide another self-limiting and saturating second half reaction. A second purge is performed to remove unused reactants and the reaction by-products in some embodiments. Pulses of the first precursor and second precursor are alternated with intervening purge operations until a desired thickness of the photoresist layer 15 is achieved.

In some embodiments, the photoresist layer 15 is formed to a thickness of about 5 nm to about 50 nm, and to a thickness of about 10 nm to about 30 nm in other embodiments. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the photoresist layer. The photoresist layer thickness are relatively uniform to facilitate processing. In some embodiments, the variation in thickness of the coating varies by no more than ±25% from the average coating thickness, in other embodiments the photoresist layer thickness varies by no more than ±10% from the average photoresist layer thickness. In some embodiments, such as high uniformity coatings on larger substrates, the evaluation of the photoresist layer uniformity may be evaluated with a 1 centimeter edge exclusion, i.e., the layer uniformity is not evaluated for portions of the coating within 1 centimeter of the edge. A person of ordinary skill in the art will recognize that additional ranges within the explicit ranges above are contemplated and are within the present disclosure.

In some embodiments, the first and second compounds or precursors are delivered into the deposition chamber with a carrier gas. The carrier gas, a purge gas, a deposition gas, or other process gas may contain nitrogen, hydrogen, argon, neon, helium, or combinations thereof.

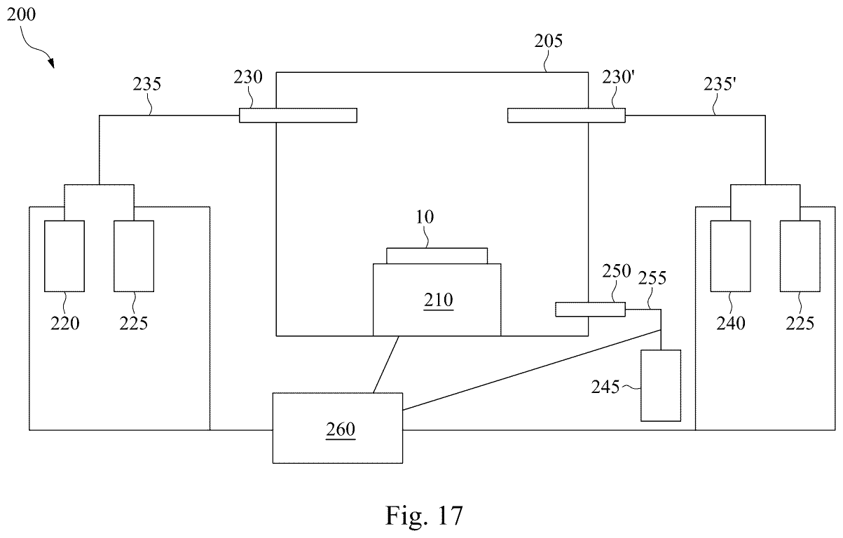

A resist layer deposition apparatus 200 according to some embodiments of the disclosure is shown in FIG. 17. In some embodiments, the deposition apparatus 200 is an ALD or CVD apparatus. The deposition apparatus 200 includes a vacuum chamber 205. A substrate support stage 210 in the vacuum chamber 205 supports a substrate 10, such as silicon wafer. In some embodiments, the substrate support stage 210 includes a heater. A first precursor or compound gas supply 220 and carrier/purge gas supply 225 are connected to an inlet 230 in the chamber via a gas line 235, and a second precursor or compound gas supply 240 and carrier/purge gas supply 225 are connected to another inlet 230′ in the chamber via another gas line 235′ in some embodiments. The chamber is evacuated, and excess reactants and reaction byproducts are removed by a vacuum pump 245 via an outlet 250 and exhaust line 255. In some embodiments, the flow rate or pulses of precursor gases and carrier/purge gases, evacuation of excess reactants and reaction byproducts, pressure inside the vacuum chamber 205, and temperature of the vacuum chamber 205 or wafer support stage 210 are controlled by a controller 260 configured to control each of these parameters.

In some embodiments, the ALD or CVD deposition described herein in reference to FIG. 17 is used to deposit the first metal complex over the substrate 10, target layer 60, or underlayer 20.

In some embodiments, the ALD or CVD deposition parameters are varied during the deposition operation to form a photoresist layer having a density gradient. In some embodiments, the density gradient photoresist layer reduces defects, such as scum and bridging; and improves the line width roughness (LWR) and line edge roughness (LER).

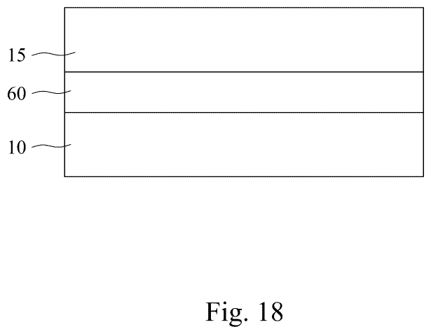

In some embodiments, a target layer 60 to be patterned is disposed over the substrate prior to forming the resist layer 15, as shown in FIG. 18. In some embodiments, the target layer 60 is a semiconductor layer; a conductive layer, such as a metallization layer; or a dielectric layer, such as a passivation layer disposed over a metallization layer. In some embodiments where the target layer 60 is a metallization layer, the target layer 60 is formed of a conductive material using metallization processes, and metal deposition techniques, including electroplating, chemical vapor deposition, atomic layer deposition, and physical vapor deposition (sputtering). Likewise, in some embodiments where the target layer 60 is a dielectric layer, the target layer 60 is formed by dielectric layer formation techniques, including thermal oxidation, chemical vapor deposition, atomic layer deposition, and physical vapor deposition. In some embodiments, the target layer 60 is a bottom antireflective coating (BARC) layer made of an organic polymer or a silicon containing material.

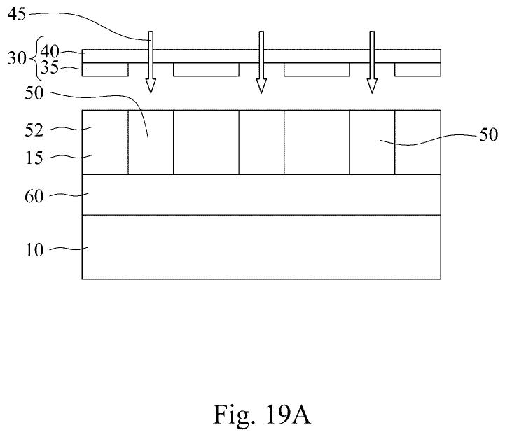

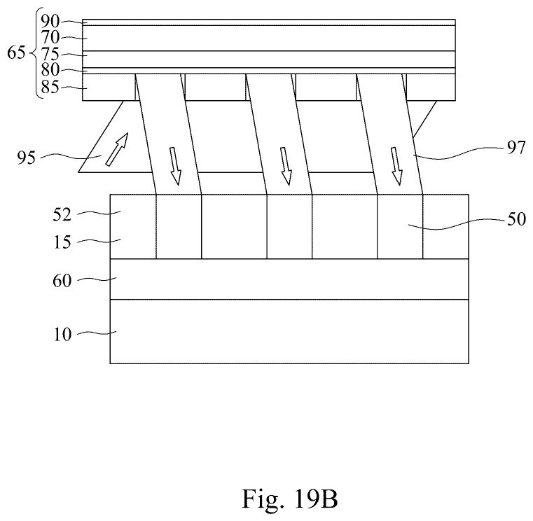

The photoresist layer 15 is subsequently selectively exposed or patternwise exposed to actinic radiation 45/97 to form exposed regions 50 and unexposed regions 52, in the photoresist layer, as shown in FIGS. 19A and 19B, and described herein in relation to FIGS. 8A and 8B.

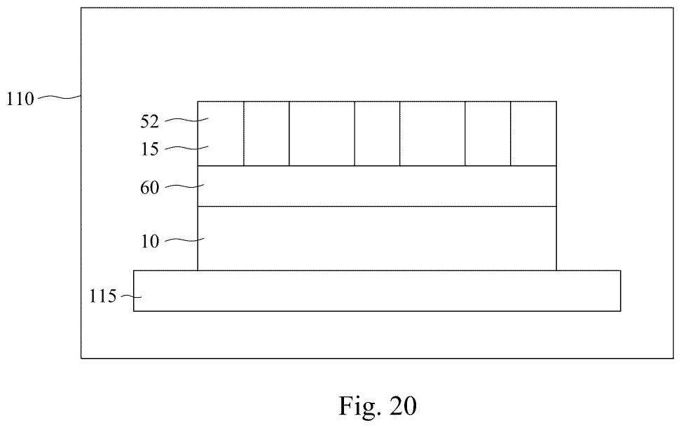

Then, as shown in FIG. 20, the selectively exposed or patternwise exposed photoresist layer 15 undergoes a post exposure baking operation, as described herein in relation to FIG. 9.

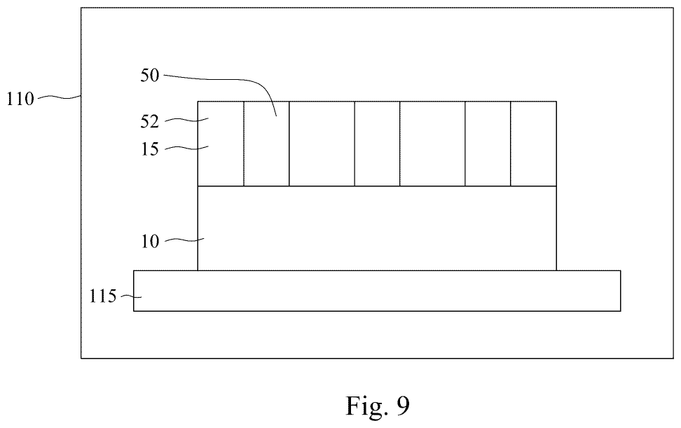

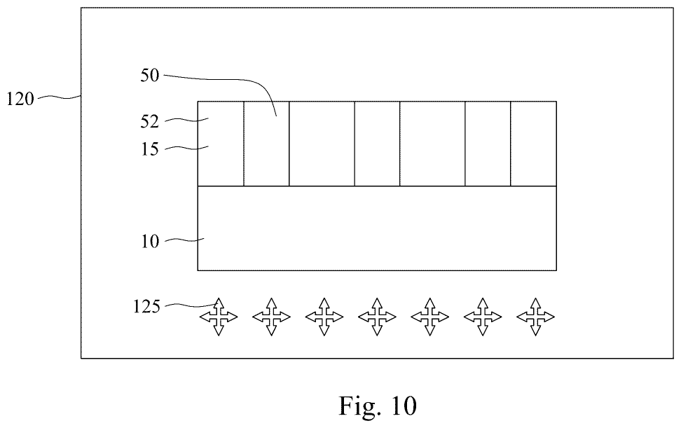

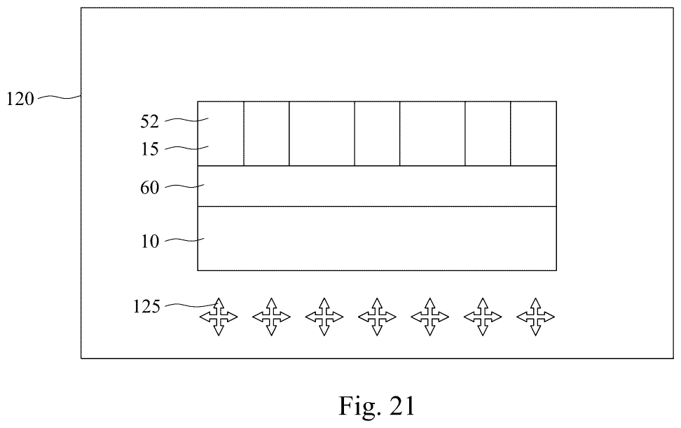

In some embodiments, as shown in FIG. 21, the selectively exposed or patternwise exposed photoresist layer undergoes an ultrasonic treatment, as described herein in relation to FIG. 10.

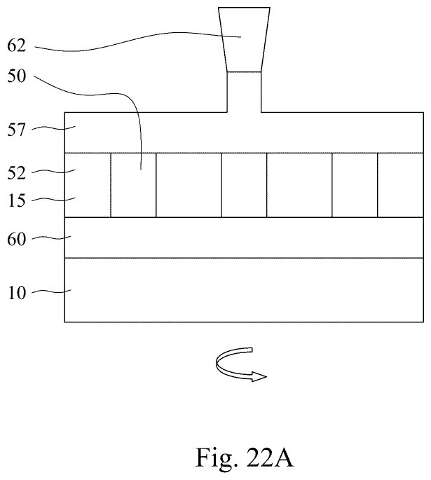

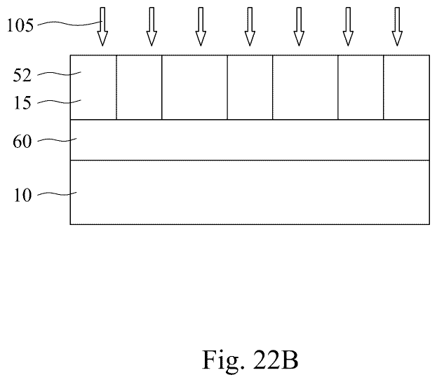

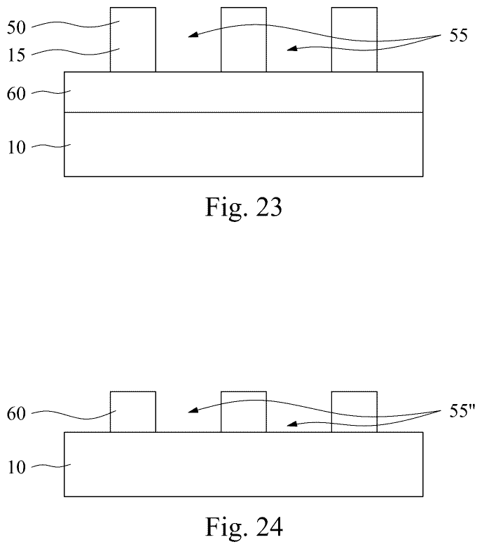

After the PEB operation S135, the photoresist layer 15 is developed in operation S150, as shown in FIGS. 22A and 22B to form a pattern of photoresist openings 55, as shown in FIG. 23. The unexposed photoresist regions 52 are developed by dispensing a developer 57 from a dispenser 62, as shown in FIG. 22A, or by a dry development operation, as shown in FIG. 22B to form the photoresist pattern 55, as shown in FIG. 23. The development operation is similar to that explained herein with reference to FIGS. 11A and 11B.

Then, as shown in FIG. 24, the pattern 55 in the photoresist layer 15 is transferred to the target layer 60 using a suitable etching operation and the photoresist layer is removed, as explained with reference to FIG. 12 to form pattern 55″ in the target layer 60.

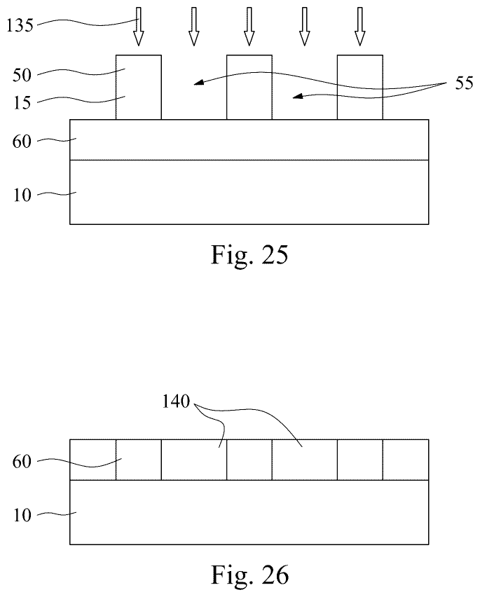

In some embodiments, the patterned photoresist layer 15 is used as a mask in an ion implantation operation. As shown in FIG. 25, the ions 135 are implanted into the target layer 60 using a suitable ion implantation apparatus or technique. After forming ion implanted regions 140, the patterned photoresist layer 15 is removed as shown in FIG. 26. A suitable photoresist stripping or plasma ashing operation is used to remove the patterned photoresist layer after the implantation operation.

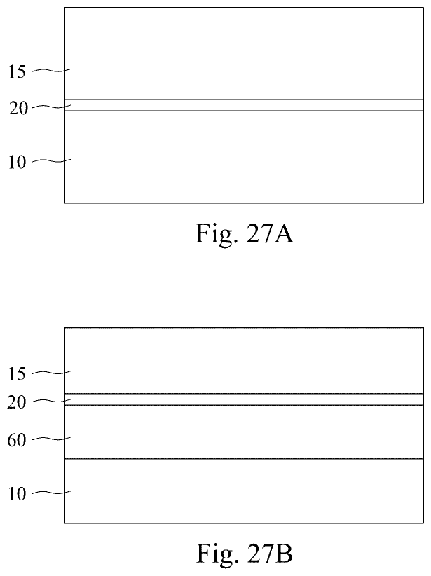

In some embodiments, a resist underlayer 20 is formed over the substrate 10 or target layer 60 before the resist layer 15 is formed, as shown in FIGS. 27A and 27B. The resist underlayer 20 improves the adhesion of the resist layer 15 to the substrate or target layer in some embodiments. In some embodiments, the resist underlayer 20 functions as a bottom anti-reflective coating. The BARC absorbs actinic radiation that passes through the photoresist layer, thereby preventing the actinic radiation from reflecting off the substrate or target layer and exposing unintended portions of the photoresist layer. Thus, the BARC improves line width roughness and line edge roughness of the photoresist pattern. In some embodiments, the BARC is made of an organic polymer; an inorganic polymer, such as a polysiloxane; or silicon-containing layer, such as a silicon oxide. The structures shown in FIGS. 27A and 27B subsequently undergo the operations disclosed herein in reference to FIG. 1 to form semiconductor devices.

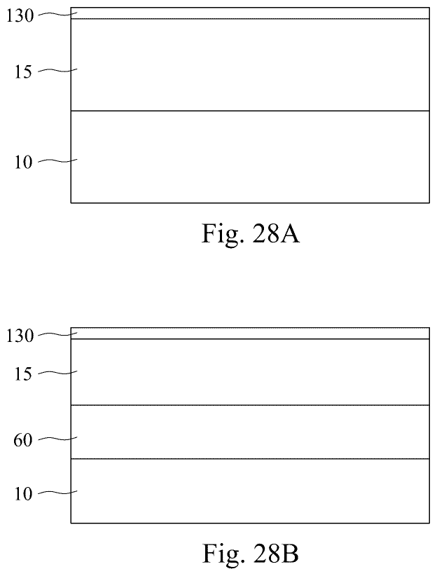

In some embodiments, a resist top layer 130 including the first metal complex is formed over the resist layer 15, as shown in FIGS. 28A and 28B. The first metal complex is subsequently diffused into the resist layer 15 during a subsequent heating operation. The top layer includes the first metal complex, a solvent, and optionally a suitable monomer, oligomer, or polymer. The structures shown in FIGS. 28A and 28B subsequently undergo the operations disclosed herein in reference to FIG. 1 to form semiconductor devices.

Other embodiments include other operations before, during, or after the operations described above. In an embodiment, the method includes forming field effect transistor structures, including fin field effect (FinFET) transistors and gate-all-around field effect (GAA FET) transistors. In some embodiments, a plurality of active fins are formed on the semiconductor substrate. Such embodiments, further include etching the substrate through the openings of the patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In another embodiment, the method includes other operations to form a plurality of gate electrodes on the semiconductor substrate. The method may further include forming gate spacers, doped source/drain regions, contacts for gate/source/drain features, etc. In another embodiment, a target pattern is to be formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

As described above, the semiconductor wafer may be an intermediate structure fabricated during processing of an IC, or a portion thereof, that may include logic circuits, memory structures, passive components (such as resistors, capacitors, and inductors), and active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, three-dimensional (3D) FETs, other memory cells, and combinations thereof.

The embodiments of the present disclosure offer advantages over existing art, though it is understood that other embodiments may offer different advantages, not all advantages are necessarily discussed herein, and that no particular advantage is required for all embodiments. Embodiments of this disclosure provide improved etching resistance of the photoresist layer. Embodiments of the disclosure provide at least 4% increase in the thickness of the photoresist layer after development than photoresist layers not using the first metal complexes of the present disclosure. Embodiments of the disclosure provide a greater than 0.3 nm improvement in the wafer acceptance testing window. Embodiments of the disclosure provide at least a 5% reduced etching rate of the photoresist layer.

An embodiment of the disclosure is a method of manufacturing a semiconductor device including depositing a photoresist composition over a substrate to form a photoresist layer and adding a metal complex to the photoresist composition. The photoresist layer is selectively exposed to actinic radiation. The selectively exposed photoresist layer is developed to form a pattern in the photoresist layer. In an embodiment, the method includes forming an underlayer comprising an underlayer composition over the substrate before depositing the photoresist composition. In an embodiment, the method includes adding the metal complex to the underlayer composition, wherein the metal complex is added to the photoresist composition by diffusion from the underlayer. In an embodiment, the metal complex is added to the photoresist composition before the photoresist composition is deposited over the substrate. In an embodiment, the metal complex is added to the photoresist composition after the photoresist composition is deposited over the substrate. In an embodiment, the method includes forming a resist top coating layer including a resist top layer composition over the photoresist layer. In an embodiment, the method includes adding the metal complex to the resist top layer composition, wherein the metal complex is added to the photoresist composition by diffusion from the resist top coating layer. In an embodiment, the method includes performing a pre-exposure heating of the photoresist layer before selectively exposing the photoresist layer to actinic radiation. In an embodiment, the metal complex is added to the photoresist composition between the pre-exposure heating and the selectively exposing the photoresist layer. In an embodiment, the metal complex is represented by a structure: M-Rₚ, where M is a first metal, R is a ligand, and 5≤p≤12. In an embodiment, the photoresist composition comprises a second metal, and the second metal is different from the first metal.

Another embodiment of the disclosure is a method of manufacturing a semiconductor device including depositing a metallic photoresist composition including a first metal complex over a substrate to form a photoresist layer and adding a second metal complex to the metallic photoresist composition. The second metal complex is different from the first metal complex. The photoresist layer is selectively exposed to actinic radiation. The selectively exposed photoresist layer is developed to form a pattern in the photoresist layer. In an embodiment, the second metal complex includes a plurality of metal complex molecules and each metal complex molecule comprises 5 to 12 crosslinking sites. In an embodiment, the method includes crosslinking the first metal complex and the second metal complex. In an embodiment, the selectively exposing the photoresist layer causes the crosslinking. In an embodiment, the method includes heating the photoresist layer or applying ultrasonic energy to the photoresist layer to cause the crosslinking.

Another embodiment of the disclosure is a method of manufacturing a semiconductor device including depositing a metallic resist layer comprising a first metal complex over a substrate and adding a second metal complex to the metallic resist layer. The first metal complex is represented by a structure: M-Rₚ, where M is a first metal, R is a ligand, and 5≤p≤12. The first metal complex and the second metal complex are made of different materials. The metallic resist layer is selectively exposed to actinic radiation after adding the second metal complex to the metallic resist layer. The metallic resist layer is developed using a dry developer after patternwise exposing the metallic resist layer to actinic radiation to form a patterned metallic resist layer. In an embodiment, the first metal is at least one selected from the group consisting of Ag, Cd, In, Sn, Sb, Te, Cs, Au, Hg, Tl, Pb, Bi, Po, At, W, Zn, and Ti. In an embodiment, R is at least one of a hydrogen, an alkene group, an alkyne group, a styryl group, an acrylate group, a methacrylate group, a cinnamate group, a branched or unbranched, cyclical, or non-cyclical C1-C20 alkyl group, a C6-C20 aryl group, a C7-C20 aralkyl group, an epoxy group, an oxetane group, a primary amino group, a secondary amino group, a tertiary amino group, or an alkoxy group.

Another embodiment of the disclosure is a photoresist composition including a first metal complex, wherein the first metal complex is represented by a structure: M-Rₚ, where M is a first metal, R is a ligand, and 5≤p≤12, and a second metal complex. The first metal complex and the second metal complex are made of different materials. In an embodiment, the first metal is at least one selected from the group consisting of Ag, Cd, In, Sn, Sb, Te, Cs, Au, Hg, Tl, Pb, Bi, Po, At, W, Zn, and Ti. In an embodiment, R is at least one of hydrogen, an alkene group, an alkyne group, a styryl group, an acrylate group, a methacrylate group, a cinnamate group, a branched or unbranched, cyclical, or non-cyclical C1-C20 alkyl group, a C6-C20 aryl group, a C7-C20 aralkyl group, an epoxy group, an oxetane group, a primary amino group, a secondary amino group, a tertiary amino group, or an alkoxy group. In an embodiment, the composition includes a solvent. In an embodiment, a concentration of the first metal complex ranges from 0.001 wt. % to 50 wt. % based on a total weight of the first metal complex and the second metal complex. In an embodiment, the first metal complex includes a plurality of metal complex molecules and each metal complex molecule comprises 5 to 12 crosslinking sites. In an embodiment, the first metal complex is a photosensitive material. In an embodiment, the first metal complex is a thermally sensitive material. In an embodiment, the first metal complex is a sonically sensitive material. In an embodiment, R is at least one selected from the group consisting of:

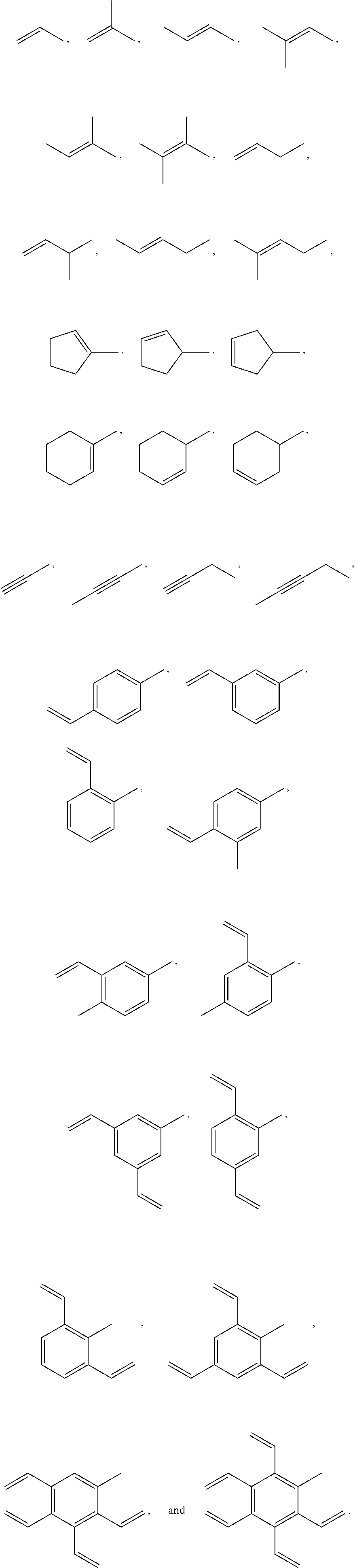

In an embodiment, R is substituted with an oxygen, nitrogen, or halogen containing group. In an embodiment, R is a ring shaped group and the ring includes an oxygen or nitrogen atom. In an embodiment, R is at least one selected from group consisting of:

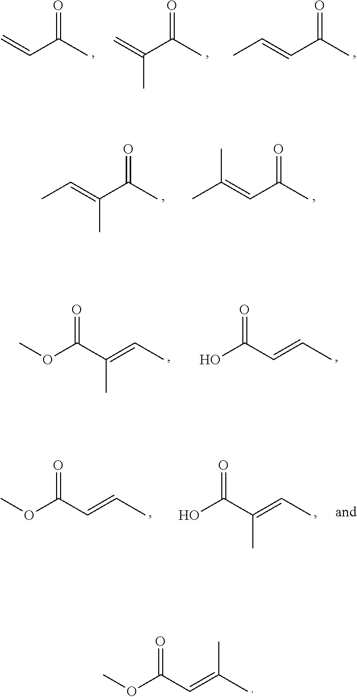

In an embodiment, R is substituted with a nitrogen, or halogen containing group. In an embodiment, R is at least one cinnamate group selected from the group consisting of:

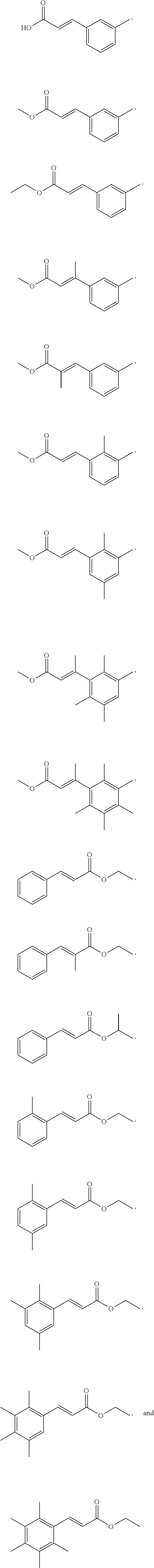

In an embodiment, the cinnamate group is substituted on a phenyl group with a nitrogen, oxygen, or halogen containing group. In an embodiment, wherein R is at least one selected from the group consisting of:

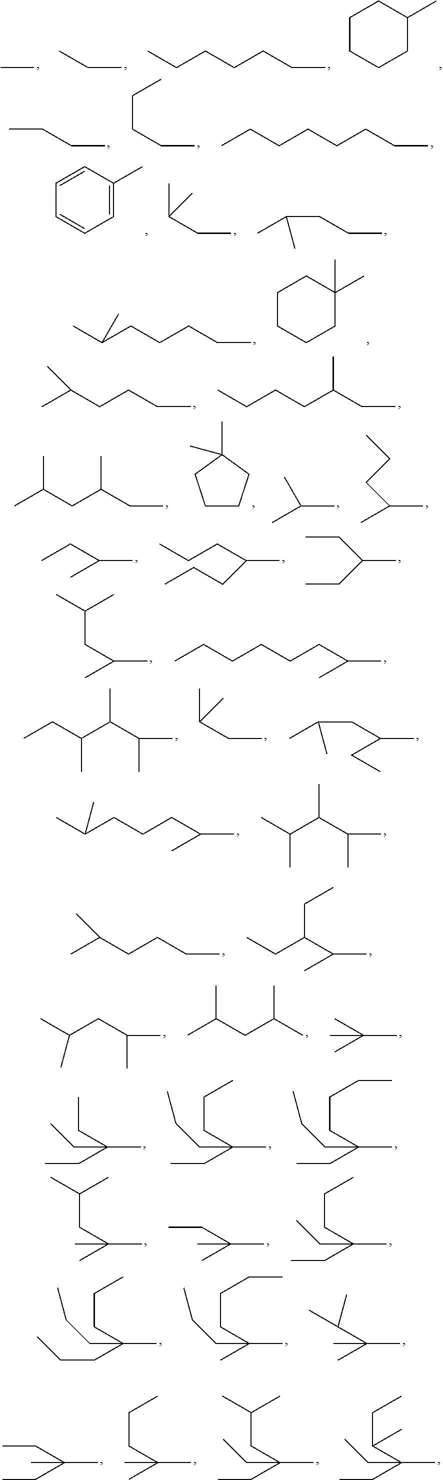

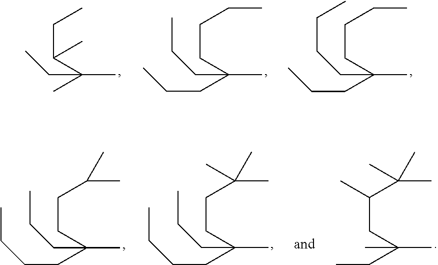

In an embodiment, R is substituted with a nitrogen, oxygen, or a halogen containing group.

Another embodiment of the disclosure is a composition including a first metal complex; and a second metal complex, wherein the first metal complex is represented by a structure:

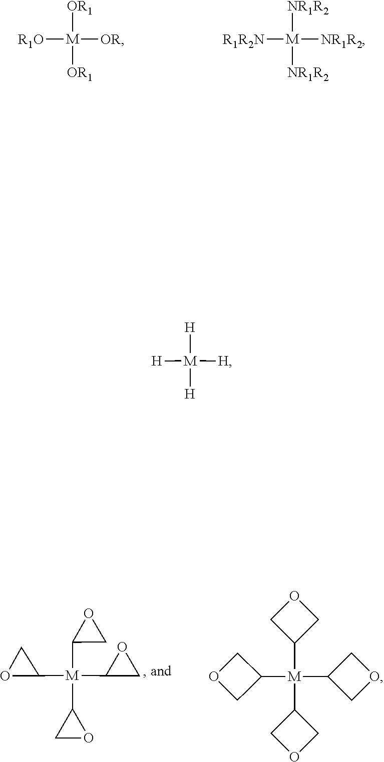

wherein R₁ and R₂ are branched or unbranched, substituted or unsubstituted, cyclic or noncyclic C1-C20 alkyl groups. The first complex and the second complex are different complexes. In an embodiment, at least one of R₁ and R₂ is substituted with a nitrogen, oxygen, or halogen containing group.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
depositing a photoresist composition over a substrate to form a photoresist layer;
adding a metal complex to the photoresist composition;
selectively exposing the photoresist layer to actinic radiation; and
developing the selectively exposed photoresist layer to form a pattern in the photoresist layer.

2. The method according to claim 1, further comprising forming an underlayer comprising an underlayer composition over the substrate before depositing the photoresist composition.

3. The method according to claim 2, further comprising adding the metal complex to the underlayer composition,
wherein the metal complex is added to the photoresist composition by diffusion from the underlayer.

4. The method according to claim 1, wherein the metal complex is added to the photoresist composition before the photoresist composition is deposited over the substrate.

5. The method according to claim 1, wherein the metal complex is added to the photoresist composition after the photoresist composition is deposited over the substrate.

6. The method according to claim 5, further comprising forming a resist top coating layer comprising a resist top layer composition over the photoresist layer.

7. The method according to claim 6, further comprising adding the metal complex to the resist top layer composition,
wherein the metal complex is added to the photoresist composition by diffusion from the resist top coating layer.

8. The method according to claim 1, further comprising performing a pre-exposure heating of the photoresist layer before selectively exposing the photoresist layer to actinic radiation.

9. The method according to claim 8, wherein the metal complex is added to the photoresist composition between the pre-exposure heating and the selectively exposing the photoresist layer.

10. The method according to claim 1, wherein the metal complex is represented by a structure: M-Rₚ, where M is a first metal, R is a ligand, and 5≤p≤12.

11. The method according to claim 10, wherein the photoresist composition comprises a second metal, and the second metal is different from the first metal.

12. The method according to claim 1, further comprising applying ultrasonic energy to the photoresist layer before the developing the selectively exposed photoresist layer.

13. A method of manufacturing a semiconductor device, comprising:
depositing a metallic photoresist composition comprising a first metal complex over a substrate to form a photoresist layer;
adding a second metal complex to the metallic photoresist composition,
wherein the second metal complex is different from the first metal complex;
selectively exposing the photoresist layer to actinic radiation; and
developing the selectively exposed photoresist layer to form a pattern in the photoresist layer.

14. The method according to claim 13, wherein the second metal complex includes a plurality of metal complex molecules and each metal complex molecule comprises 5 to 12 crosslinking sites.

15. The method according to claim 14, further comprising crosslinking the first metal complex and the second metal complex.

16. The method according to claim 15, wherein the selectively exposing the photoresist layer causes the crosslinking.

17. The method according to claim 15, further comprising heating the photoresist layer or applying ultrasonic energy to the photoresist layer to cause the crosslinking.

18. A photoresist composition, comprising:
a first metal complex,
wherein the first metal complex is represented by a structure:
M-Rₚ, where M is a first metal, R is a ligand, and 5≤p≤12; and
a second metal complex,
wherein the first metal complex and the second metal complex are made of different materials.

19. The composition of claim 18, wherein the first metal is at least one selected from the group consisting of Ag, Cd, In, Sn, Sb, Te, Cs, Au, Hg, Tl, Pb, Bi, Po, At, W, Zn, and Ti.

20. The composition of claim 18, wherein R is at least one of hydrogen, an alkene group, an alkyne group, a styryl group, an acrylate group, a methacrylate group, a cinnamate group, a branched or unbranched, cyclical, or non-cyclical C1-C20 alkyl group, a C6-C20 aryl group, a C7-C20 aralkyl group, an epoxy group, an oxetane group, a primary amino group, a secondary amino group, a tertiary amino group, or an alkoxy group.
